(19) United States
(12) Patent Application Publication
(10) Pub. No.: US 2024/0237369 A1
(43) Pub. Date: Jul. 11, 2024

(54) SOLID-STATE IMAGING DEVICE AND METHOD OF MANUFACTURING SOLID-STATE IMAGING DEVICE

(71) Applicant: SONY SEMICONDUCTOR SOLUTIONS CORPORATION, KANAGAWA (JP)

(72) Inventors: YUTA OKABE, KANAGAWA (JP); OSAMU ENOKI, KANAGAWA (JP); SYUUITI TAKIZAWA, KANAGAWA (JP)

(21) Appl. No.: 18/557,190

(22) PCT Filed: Jan. 17, 2022
(86) PCT No.: PCT/JP2022/001454

§ 371 Date: Oct. 25, 2023

(30) Foreign Application Priority Data
May 18, 2021 (JP) 2021-083843

(51) Int. Cl. H10K 30/85; H10K 39/32

(52) U.S. Cl. CPC H10K 30/85; H10K 39/32

(57) ABSTRACT

A solid-state imaging device includes a photoelectric conversion element. The photoelectric conversion element includes a first electrode, an electron transport layer, and a photoelectric conversion layer. The first electrode is disposed on a substrate and the photoelectric conversion layer is disposed on the first electrode. The electron transport layer is disposed between the first electrode and the photoelectric conversion layer and includes a buffer layer and a particulate layer. The buffer layer has an ionization potential larger than a work function of the first electrode and an electron affinity larger than the photoelectric conversion layer. Then, the particulate layer includes particulates that contain conductive zinc oxide as a main component.

### TECHNICAL FIELD

The present disclosure relates to a solid-state imaging device and a method of manufacturing the solid-state imaging device.

### BACKGROUND ART

For example, Patent Literature 1 discloses a photoelectric conversion element and a method of manufacturing the photoelectric conversion element. The photoelectric conversion element includes a structure in which a lower electrode, a zinc oxide (ZnO) nanoparticle layer, a photoelectric conversion layer, a hole transport layer, and an upper electrode are sequentially stacked on a substrate. The zinc oxide nanoparticle layer is an electron transport layer. The zinc oxide nanoparticle layer is film formed by synthesizing zinc oxide nanoparticles in a solution, and applying and heating this solution.

### CITATION LIST

### Patent Literature

PTL 1: Japanese Unexamined Patent Application Publication No. 2014-220333

### SUMMARY OF THE INVENTION

In the photoelectric conversion element and the method of manufacturing the photoelectric conversion element described above, a zinc oxide nanoparticle layer is formed by using a coating method, thus resulting in variations in wettability between an underlying lower electrode and the zinc oxide nanoparticle layer. Therefore, it is desired to improve adhesion of the zinc oxide nanoparticle layer to the lower electrode and to reduce peeling of a coated film on the zinc oxide nanoparticle layer, without affecting electric conductivity or dispersibility of zinc oxide nanoparticles.

The present disclosure provides a solid-state imaging device including a photoelectric conversion element that is able to improve adhesion of an electron transport layer to an electrode and to reduce peeling of a coated film without affecting electric conductivity or dispersibility of particulates, and a method of manufacturing the solid-state imaging device.

A solid-state imaging device according to a first embodiment of the present disclosure includes a photoelectric conversion element, the photoelectric conversion element including a first electrode disposed on a substrate, a photoelectric conversion layer disposed on the first electrode, and an electron transport layer disposed between the first electrode and the photoelectric conversion layer and including a buffer layer and a particulate layer. The buffer layer has an ionization potential larger than a work function of the first electrode and an electron affinity larger than the photoelectric conversion layer. The particulate layer is disposed between the buffer layer and the photoelectric conversion layer and includes particulates that contain conductive zinc oxide as a main component.

A method of manufacturing a solid-state imaging device according to a second embodiment of the present disclosure includes: forming a first electrode on a substrate; forming a buffer layer that has an n-semiconductor or an n-type organic semiconductor as a main component by applying an ink liquid, in which a zinc precursor is dissolved, on the first electrode and heating the ink liquid; and forming, on the buffer layer, a particulate layer including particulates that have conductive zinc oxide as a main component to form an electron transport layer of a photoelectric conversion element, the electron transport layer including the buffer layer and the particulate layer.

### BRIEF DESCRIPTION OF THE DRAWINGS

FIG. 1 is a cross-sectional view of a main part of a solid-state imaging device according to a first embodiment of the present disclosure.

FIG. 2 is an enlarged schematic cross-sectional view of a photoelectric conversion element of the solid-state imaging device illustrated in FIG. 1 enlarged.

FIG. 3 is a diagram illustrating a relationship between a position of each layer of the photoelectric conversion element illustrated in FIG. 2 and energy of an ionization potential.

FIG. 4 is a diagram illustrating an emission spectrum of an electron transport layer of the photoelectric conversion element illustrated in FIG. 2.

FIG. 5 is a flowchart explaining a method of manufacturing the solid-state imaging device according to the first embodiment.

FIG. 6A is a perspective view explaining a surface state prior to high-temperature annealing of a buffer layer of the electron transport layer illustrated in FIG. 2.

FIG. 6B is a plan view explaining the surface state of the buffer layer illustrated in FIG. 6A.

FIG. 7A is a perspective view corresponding to FIG. 6A and explaining the surface state after the high-temperature annealing of the buffer layer illustrated in FIG. 6A.

FIG. 7B is a plan view corresponding to FIG. 6B and explaining the surface state of the buffer layer illustrated in FIG. 7A.

FIG. 8A is a schematic perspective view explaining a state in which organic functional groups are bonded to particulates in a particulate layer of the electron transport layer illustrated in FIG. 2.

FIG. 8B is a schematic perspective view corresponding to FIG. 8A and explaining a state after organic compounds are bonded to the particulates illustrated in FIG. 8A.

FIG. 9 is diagram illustrating the emission spectrum after passivation treatment is applied to a surface of particulates.

FIG. 10 is a diagram explaining defect emission intensity with respect to band-edge emission intensity.

FIG. 11 is a diagram in a tabular form illustrating characteristic evaluation results of a photoelectric conversion element according to a comparative example and a photoelectric conversion element according to an example of the first embodiment.

FIG. 12A is a diagram explaining adhesion of the electron transport layer to a first electrode of the photoelectric conversion element illustrated in FIG. 2.

FIG. 12B is a diagram explaining peeling of a coated film of the electron transport layer with respect to the first electrode of the photoelectric conversion element illustrated in FIG. 2.

FIG. 13A is a diagram corresponding to FIG. 12A and explaining the adhesion of the electron transport layer to an electrode according to the comparative example.

FIG. 13B is a diagram corresponding to FIG. 12A and explaining the peeling of the coated film of the electron transport layer to the electrode according to the comparative example.

FIG. 14 is a block diagram explaining a schematic configuration of an electronic apparatus according to the first embodiment.

FIG. 15 is a schematic view of an example of a configuration of a CMOS imaging device according to a second embodiment of the present disclosure.

FIG. 16 is a block diagram depicting an example of schematic configuration of a vehicle control system.

FIG. 17 is a diagram of assistance in explaining an example of installation positions of an outside-vehicle information detecting section and an imaging section.

FIG. 18 is a view depicting an example of a schematic configuration of an endoscopic surgery system.

FIG. 19 is a block diagram depicting an example of a functional configuration of a camera head and a camera control unit (CCU).

### MODES FOR CARRYING OUT THE INVENTION

In the following, embodiments of the present disclosure are described in detail with reference to the drawings. It is to be noted that description is given in the following order.

### 1. First Embodiment

A first embodiment explains an example in which the present technology is applied to a solid-state imaging device.

### 2. Second Embodiment

A second embodiment explains an example in which the present technology is applied to a CMOS imaging device.

### 3. Example of Practical Application to a Mobile Body

Description is given of an example in which the present technology is applied to a vehicle control system that is an example of a mobile body control system.

### 4. Example of Practical Application to an Endoscopic Surgery System

Description is given of an example in which the present technology is applied to an endoscopic surgery system.

### 5. Other Embodiments

### 1. First Embodiment

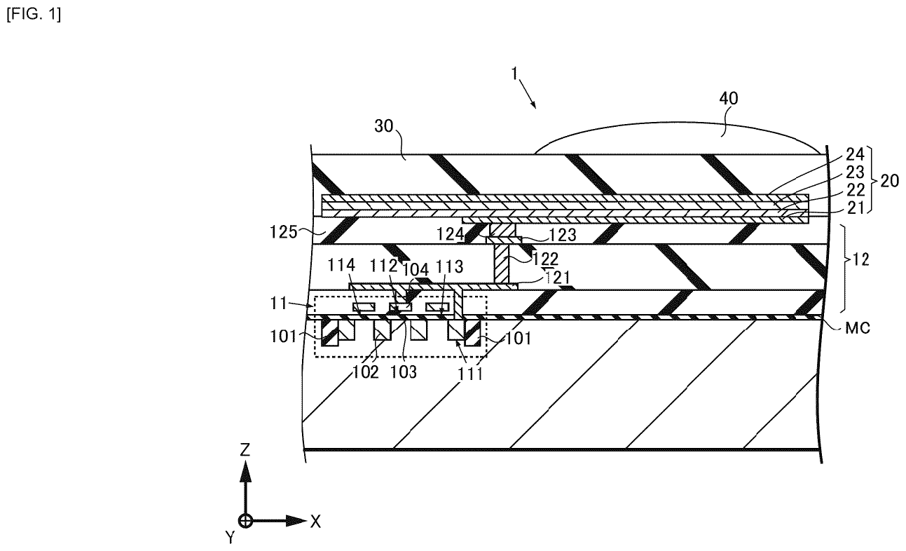

With reference to FIG. 1 to FIG. 14, description is given of a solid-state imaging device 1 according to the first embodiment of the present disclosure.

Here, an arrow X direction depicted in the figures appropriately indicates a planar direction of the solid-state imaging device 1 placed on a plane for convenience. An arrow Y direction indicates another planar direction that is orthogonal to the arrow X direction. In addition, an arrow Z direction indicates an upward direction that is orthogonal to the arrow X direction and the arrow Y direction. That is, the arrow X direction, the arrow Y direction, and the arrow Z direction exactly correspond to an X-axis direction, a Y-axis direction, and a Z-axis direction of a three-dimensional coordinate system, respectively.

It is to be noted that each of these directions is illustrated to aid understanding of explanations and is not intended to limit a direction of the present technology.

### Configuration of the Solid-state Imaging Device 1

### (1) Schematic Configuration of the Solid-state Imaging Device 1

FIG. 1 illustrates an example of a cross-sectional configuration of a main part that includes a photoelectric conversion element 20 and a control circuit 11 of the solid-state imaging device 1.

The solid-state imaging device 1 includes a substrate 10, the control circuit 11 disposed on the substrate 10, and the photoelectric conversion element 20.

A semiconductor substrate including monocrystalline silicon (Si), for example, is used for the substrate 10.

The control circuit 11 is disposed on a main surface part of the substrate 10. Here, a main surface MC of the substrate 10 is an upper surface in FIG. 1 and is a main surface that forms semiconductor devices including a transistor, a resistor, and a capacitor. The control circuit 11 is coupled to the photoelectric conversion element 20. The control circuit 11 includes a charge storage unit 111, an amplification transistor 112, a reset transistor 113, and a selection transistor 114.

The amplification transistor 112 is disposed on the main surface part of the substrate 10 within a region surrounded by a device separation region 101. The amplification transistor 112 includes a channel formation region, a gate insulating film 103, a gate electrode 104, and a pair of main electrodes 102 used as a source region and a drain region. The channel formation region is formed on the main surface part of the substrate 10 or a main surface part of a well region that is not illustrated and is formed on the main surface part of the substrate 10. The main electrodes 102 are n-type semiconductor regions. That is, the amplification transistor 112 is an n-channel insulated gate field effect transistor (IGFET).

Here, the IGFET is used in a sense including at least a metal-oxide-semiconductor field-effect transistor (MOSFET) and a metal-insulator-semiconductor field-effect transistor (MISFET).

Both the reset transistor 113 and the selection transistor 114 are disposed on the main surface part of the substrate 10 within the region surrounded by the device separation region 101. Similarly to the amplification transistor 112, each of the reset transistor 113 and the selection transistor 114 includes the channel forming region, the gate insulating film 103, and the pair of main electrodes 102, and includes the n-channel IGFET.

One of the main electrodes 102 of the amplification transistor 112 is coupled to one of the main electrodes 102 of the reset transistor 113. The gate electrode 104 of the amplification transistor 112 and another main electrode 102 of the reset transistor 113 are coupled to the photoelectric conversion element 20. Here, a pn junction part between the other main electrode 102 of the reset transistor 113 and the substrate 10 includes the charge storage unit 111.

In addition, another main electrode of the amplification transistor 112 is coupled to one main electrode 102 of the selection transistor 114, and another main electrode 102 of the selection transistor 114 is coupled to a signal line that is not illustrated.

A wiring layer 12 is disposed on the main surface MC of the substrate 10. The control circuit 11 is coupled to the photoelectric conversion element 20 through each of wiring 121, wiring 122, wiring 123, and wiring 124 that have a plurality of layers and are disposed on the wiring layer 12. It is to be noted that the wiring layer 12 includes an insulator 125 formed of a plurality of layers of insulating films that insulate between an upper wiring line and a lower wiring line.

The photoelectric conversion element 20 is disposed on the wiring layer 12 and a protective film 30 is disposed on the photoelectric conversion element 20. In a region corresponding to the photoelectric conversion element 20, a light receiving lens 40 is disposed on the protective film 30.

### (2) Configuration of the Photoelectric Converter 20

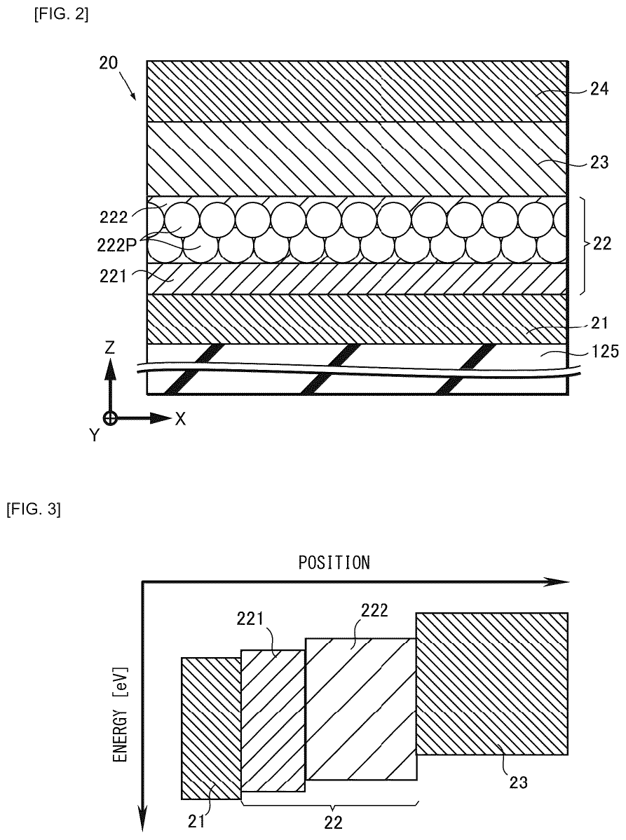

FIG. 2 illustrates an example of a cross-sectional configuration of the photoelectric conversion element 20.

The photoelectric conversion element 20 includes a first electrode (lower electrode) 21, an electron transport layer 22, a photoelectric conversion layer 23, and a second electrode (upper electrode) 24.

The first electrode 21 is disposed on the substrate 10. In detail, the first electrode 21 is disposed on the substrate 10 via the wiring layer 12. The first electrode 21 is coupled to the control circuit 11 through the wiring line 121 to the wiring line 124 of the wiring layer 12. The first electrode 21 takes out signal charges (electrons) generated in the photoelectric conversion layer 23.

The first electrode 21 is formed by at least one conductive material selected from the group of gold (Au), silver (Ag), copper (Cu), and aluminum (Al), for example. In this case, the first electrode 21 is set to have a thickness of 10 nm or more and 100 nm or less, for example.

In addition, the first electrode 21 may be formed of a light transmissive conductive material. It is possible to use ITO (Indium-Tin-Oxide), for example, for the light transmissive conductive material.

Furthermore, the firsts electrode 21 may be formed of a tin oxide (SnO2) based material or a zinc oxide (Zn) based material. The tin oxide-based material is a material obtained by adding a dopant to tin oxide. As the zinc oxide-based material, it is possible to practically use aluminum zinc oxide (AZO), gallium zinc oxide (GZO), or indium zinc oxide (IZO), for example. Aluminum zinc oxide is obtained by adding aluminum as the dopant to zinc oxide. Gallium zinc oxide, is obtained by adding gallium (Ga) as the dopant to zinc oxide. Indium zinc oxide is obtained by adding indium (In) as the dopant to zinc oxide.

In addition to the materials exemplified above, the first electrode 21 may be formed by at least one material selected from IGZO, CuI, InSbO4, ZnMgO, CuInO2, MgIn2O4, CdO, and ZnSnO3.

In a case where the first electrode 21 is formed by the light transmissive conductive material, the first electrode 21 is set to have the thickness of 50 nm or more and 500 nm or less, for example.

The electron transport layer 22 is disposed between the first electrode 21 and the photoelectric conversion layer 23 and formed on the first electrode 21. The electron transport layer 22 includes a buffer layer 221 disposed on the first electrode 21 and a particulate layer 222 disposed on the buffer layer 221.

FIG. 3 illustrates an example of a relationship between a position of each layer of the photoelectric conversion element 20 and energy of an ionization potential. A horizontal axis indicates the position of each of the first electrode 21, the buffer layer 221 and the particulate layer 222 of the electron transport layer 22, and the photoelectric conversion element 23, when viewed from left to right. A vertical axis indicates the energy [eV].

The buffer layer 221 is configured to have the ionization potential larger than a work function of the first electrode 21 and an electron affinity larger than the photoelectric conversion layer 23. Expressed differently, the buffer layer 221 has a large hole injection barrier against the first electrode 21 and further has higher mobility of electrons that are photocurrent carriers than the mobility of holes. In addition, in the photoelectric conversion element 20, an energy level of a conductor or a lowest unoccupied molecular orbital (LUMO: Lowest Unoccupied Molecular Orbital) is formed deeper in the order of the photoelectric conversion layer 23, the particulate layer 222, and the buffer layer 221.

The buffer layer 221 is formed by an n-type semiconductor, for example. Examples of the n-type semiconductor include at least one inorganic material selected from titanium oxide (TiO2), zinc oxide, zinc sulfide (ZnS), SrTiO3, niobium oxide (Nb2O5), tungsten oxide (WO3), indium oxide (In2O3), CuTiO3, tin oxide (SnO2), InGaZnO4, InTiO2, and β-Ga2O3.

In addition, the buffer layer 221 may be formed by an n-type organic semiconductor, for example. As the n-type organic semiconductor material, it is possible to practically use an organic metal dye complex-formed with an organic material and a transition metal ion represented by phthalocyanine zinc (II); fullerene or a fullerene derivative; a non-fullerene acceptor represented by an ITIC or BTP derivative, or the like, for example.

The buffer layer 221 is set to have the thickness of 10 nm or more and 50 nm or less, for example.

The buffer layer 221 is film formed through the use of a sol-gel (Sol-gel) method, for example. Specifically, in a case where zinc oxide is used, for example, the buffer layer 221 is film formed by applying an ink liquid, in which a precursor of zinc (Zn) is dissolved, on a surface of the first electrode 21 and heating the ink liquid.

The particulate layer 222 contains particulates 222P that have conductive zinc oxide as a main component. A mean primary particle size of the particulates 222P is set to 1 nm or more or 20 nm or less, for example. In addition, the particulate layer 222 is formed thicker than the thickness of the buffer layer 221. Then, the electron transport layer 22 is set to have the thickness of 400 nm or less, for example, the thickness including the thickness of the buffer layer 221 and the thickness of the particulate layer 222.

As the conductive zinc oxide, it is possible to use at least one selected from the group consisting of, for example, boron (B)-doped zinc oxide, aluminum-doped zinc oxide, and gallium (Cd)-doped zinc oxide.

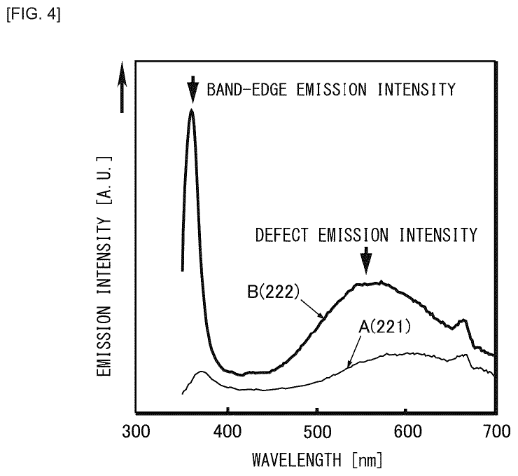

FIG. 4 illustrates an example of an emission spectrum of the electron transport layer 22. The horizontal axis indicates a wavelength. The vertical axis indicates emission intensity. Symbol A denotes the emission intensity of the buffer layer 221 with respect to the wavelength, the buffer layer 221 being formed by zinc oxide. Symbol B denotes the emission intensity of the particulate layer 222 with respect to the wavelength, the particulate layer 222 being formed by the particulates 222P that have the conductive zinc oxide as the main component.

In the particulate layer 222, as denoted by Symbol A, band-edge emission intensity is seen in the wavelengths ranging from 350 nm to 400 nm, and the defect emission intensity is seen in the wavelengths ranging from 400 nm to 700 nm.

Here, in a case where the band-edge emission intensity is strength L1 and the defect emission intensity is strength L2, an emission intensity ratio (L1/L2) of the particular layer 222 is formed to be 1 or more. That is, the particulate layer 222 is configured to reduce defects of an interface with the photoelectric conversion layer 23 and improve photoelectric conversion efficiency and optical responsivity.

The photoelectric conversion layer 23 is configured to absorb light in a selective wavelength region to perform photoelectric conversion or transmit light in other wavelength regions. The photoelectric conversion layer 23 includes an organic dye, for example. For the organic dye, it is possible to practically use quinacridone (QD) and derivatives of quinacridone or sub-phthalocyanine and derivatives of sub-phthalocyanine, for example.

In addition, as a blue organic dye, it is possible to use a coumarin derivative, a silole derivative, or fluorene, for example. As a green organic dye, it is possible to use a rhodamine derivative, for example. As a red organic dye, it is possible to use zinc phthalocyanine, for example.

The photoelectric conversion layer 23 may include an inorganic semiconductor, in addition to the organic dye. As the inorganic semiconductor, it is possible to use one selected from TiO2, ZnO, WO3, NiO, MoO3, CuO, Ga2O3, SrTiO3, SnO2, InSnOx, Nb2O3, MnO2, V2O3, CrO, CuInSe2, CuInS2, AgInS2, Si, PbS, PbSe, PbTe, CdS, CdSe, CdTe, Fe2O3, GaAs, GaP, InP, InAs, Ge, In2S3, Bi2S3, ZnSe, ZnTe and ZnS.

In addition, the photoelectric conversion layer 23 may contain a colloidal quantum dot or an organic-inorganic perovskite compound represented by CH3NH3PbX3 (X: halogen), for example. The photoelectric conversion layer 23 is set to have the thickness of 0.05 μm or more and 10 μm or less.

The photoelectric conversion layer 23 is formed by using a film-formation method of any of a spin coating method, a blade coating method, a slit die coating method, a screen printing method, a bar coater method, a mold coating method, a print transfer method, an immersion pulling method, an inkjet method, a spray method, and a vacuum coating method. The film formation method for the photoelectric conversion layer 23 is selected appropriately according to a targeted characteristic including thickness control or orientation control.

The second electrode 24 takes out the signal charges (holes) generated in the photoelectric conversion layer 23. Similarly to the first electrode 21, the second electrode 24 is formed by the light transmissive conductive material, for example, ITO. In addition, similarly to the first electrode 21, the second electrode 24 may be formed by an SnO2-based material, a ZnO-based material, or the like. The second electrode 24 is set to have the thickness of 50 nm or more and 500 nm or less, for example.

### (3) Method of Manufacturing the Solid-State Imaging Device 1

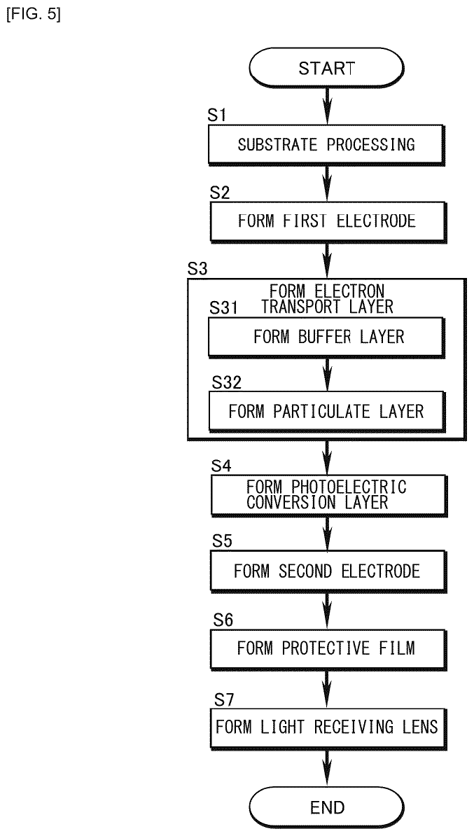

FIG. 5 illustrates an example of a method of manufacturing the solid-state imaging device 1, and particularly a method of manufacturing the photoelectric conversion element 20.

First, the substrate 10 is prepared, and the control circuit 11, the wiring layer 12, or the like are formed on the substrate 10 (step S1. See FIG. 1.).

Next, the first electrode 21 of the photoelectric conversion element 20 is formed on the wiring layer 12 (step S2. See FIG. 2.).

Then, the electron transport layer 22 is formed on the first electrode 21 (step S3).

In the electron transport layer 22, the buffer layer 221 is formed first (step S31). In a case where zinc oxide is used, for example, using the sol-gel method, the buffer layer 221 is film formed by applying the ink liquid, in which the zinc precursor is dissolved, on the surface of the first electrode 21 and heating the ink liquid. The heating is set to a temperature of 150° C. or higher and 250° C. or lower.

Then, the particulate layer 222 is formed on the buffer layer 221 (step S32). The particulate layer 222 is film formed by the coating method, for example.

Once the particulate layer 222 is formed, the electron transport layer 22 including the buffer layer 221 and the particulate layer 222 is completed.

Next, the photoelectric conversion layer 23 is formed on the electron transport layer 22 (step S4). Subsequently, the second electrode 24 is formed on the photoelectric conversion layer 23 (step S5). This completes the photoelectric conversion element 20.

Next, the protective film 30 is formed on the photoelectric conversion element 20 (step S6. See FIG. 1.). The light receiving lens 40 is formed on the protective film 30 (Step S7. See FIG. 1.). This completes the solid-state imaging device 1.

### (4) First Example

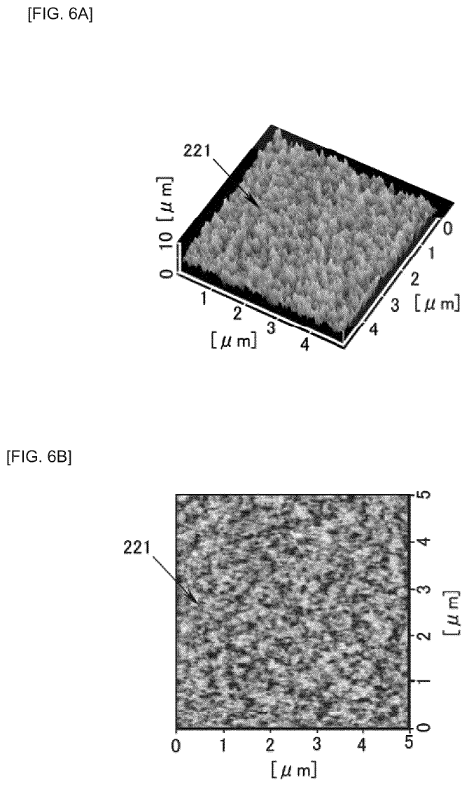

FIG. 6A and FIG. 6B illustrate an example of a surface of the buffer layer 221 of the electron transport layer 22 according to a first example. Here, in some cases, the photoelectric conversion element 20 according to the first example may be described as a “photoelectric conversion element 20(1)”.

The buffer layer 221 is formed by zinc oxide, for example, and is in a state prior to high-temperature annealing. The buffer layer 221 is amorphous. The surface of the buffer layer 221 has arithmetic mean roughness Ra of 0.8 or more and 1.0 or less.

### (2) Second Example

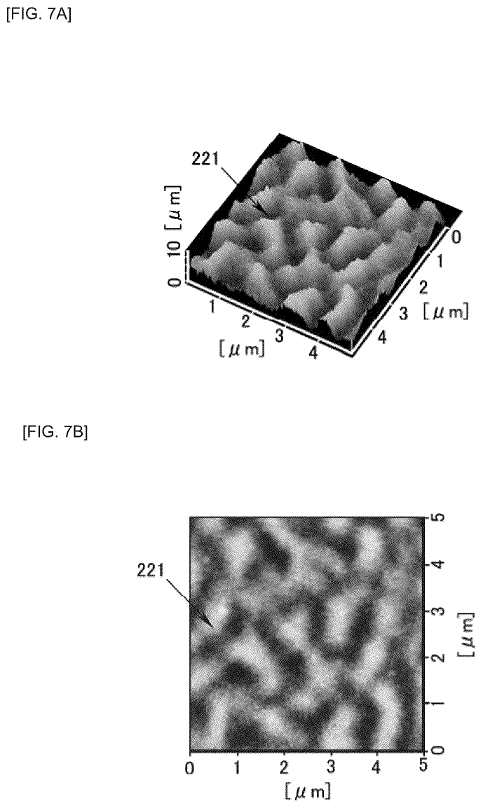

FIG. 7A and FIG. 7B illustrate an example of a surface of the buffer layer 221 of the electron transport layer 22 according to a second example. Similarly, the photoelectric conversion element 20 according to the second example may be described as a “photoelectric conversion element 20(2)”.

The buffer layer 221 is formed by zinc oxide, for example, and is in a state after the high-temperature annealing. The high-temperature annealing crystallizes the buffer layer 221 and makes the buffer layer 221 polycrystalline. The surface of the buffer layer 221 has the arithmetic mean roughness Ra of 8 or more and 12 or less.

### (6) Third Example

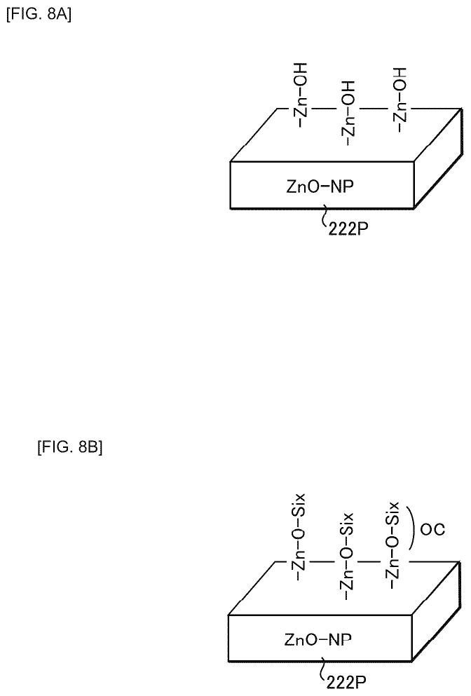

FIG. 8A illustrates an example of the particulate layer 222 of the electron transport layer 22 according to a third example, the particulate layer 222 being in a state in which organic functional groups are bonded to the particulates 222P. Similarly, the photoelectric conversion element 20 according to the third example may be described as a “photoelectric conversion element 20(3)”. The organic functional groups are hydroxy (OH) groups, for example.

Then, FIG. 8B illustrates an example of the particulate layer 222 according to the third example after passivation treatment is applied to a surface of the particulate layer 222. The passivation treatment bonds an organic compound OC such as a silane coupling agent to the surface of the particulates 222P.

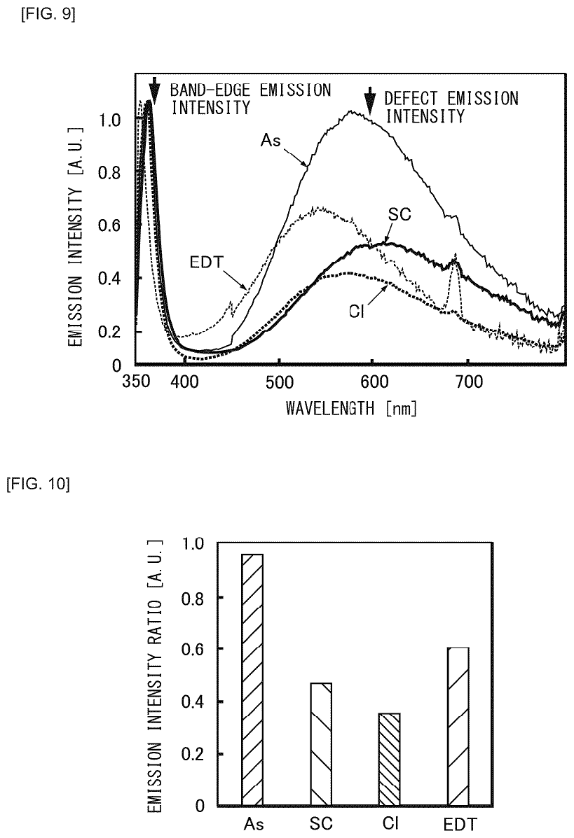

FIG. 9 illustrates the emission spectrum before and after the passivation treatment is applied to the surface of the particulates 222P. The horizontal axis indicates the wavelength and the vertical axis indicates the emission intensity. At the wavelength of 360 nm, a peak of the emission intensity is the band-edge emission of the particulates 222P. The emission intensity near the wavelength of 600 nm is the emission intensity from a defect level.

Symbol “As” denotes the emission spectrum before the passivation treatment is applied. Each of Symbol “SC”, Symbol “Cl”, and Symbol “EDT” denotes the emission spectrum after the passivation treatment is applied. “SC” denotes the emission spectrum after the passivation treatment is applied using the silane coupling agent. “Cl” denotes the emission spectrum after the passivation treatment is applied using chlorine (Cl) ionized from aluminum chloride. “EDT” denotes the emission spectrum after the passivation treatment is applied using 1,2-ethanediothiol.

After application of the passivation treatment, the emission intensity from the defect level is reduced as compared with before the application of the passivation treatment illustrated in “As”.

FIG. 10 illustrates a ratio of the band-edge emission intensity in FIG. 9 and the emission intensity from the defect level. The smaller the emission intensity ratio is, the more suppressed the emission from the defect level is. That is, the surface defects of the particulates 222P are reduced by application of the passivation treatment. The reduction of the defects makes it possible to reduce the photoelectric conversion efficiency or the optical response speed of devices. Here, defect suppression has a profound effect, after application of the passivation treatment to which Symbol “Cl” is assigned.

### (7) First Comparative Example and Second Comparative Example

Here, description is given of a photoelectric conversion element 20A according to a first comparative example and a photoelectric conversion element 20B according to a second comparative example.

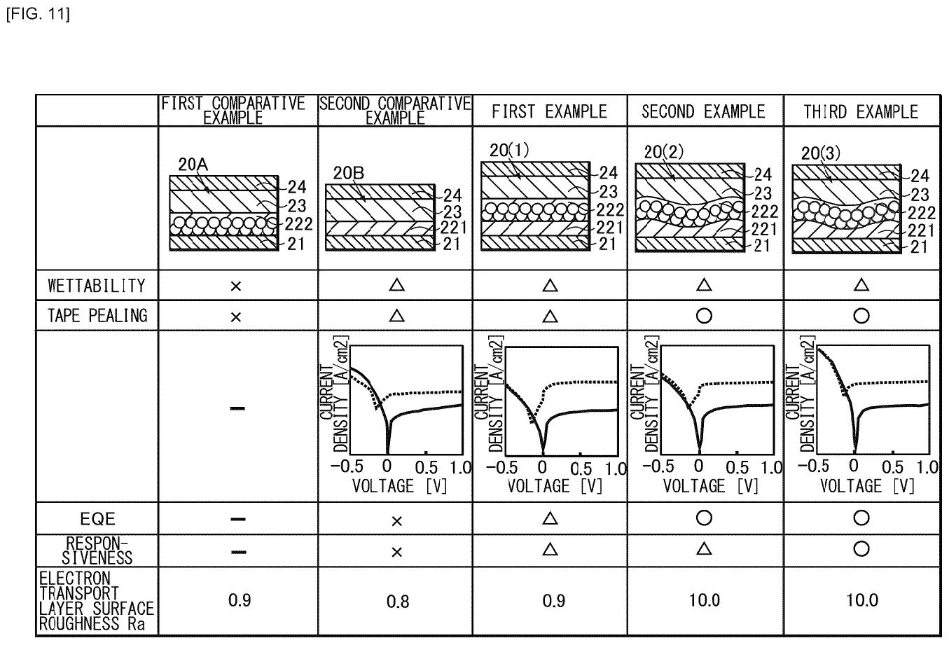

FIG. 11 illustrates an example of characteristic evaluation results of the photoelectric conversion element 20(1) to the photoelectric conversion element 20(3) according to the first example to the third example, the photoelectric conversion element 20A according to the first comparative example, and the photoelectric conversion element 20B according to the second comparative example.

The photoelectric conversion element 20A according to the first comparative example includes the first electrode 21, the particulate layer 222, the photoelectric conversion layer 23, and the second electrode 24. That is, the electron transport layer 22 is formed by the particulate layer 222.

In contrast, the photoelectric conversion element 20B according to the second comparative example includes the first electrode 21, the buffer layer 221, the photoelectric layer 23, and the second electrode 24. That is, the electron transport layer 22 is formed by the buffer layer 221.

### (8) Characteristic Evaluation Results of the Examples Relative to the Comparative Examples

For the photoelectric conversion element 20A according to the first comparative example, each item of wettability, tape peeling, and surface roughness of the electron transport layer 22 was evaluated.

The wettability evaluates adhesion between the first electrode 21 and the electron transport layer 22 by means of an appearance check. In a case where the adhesion is 100%, the evaluation result is “Excellent” and is indicated by Symbol “o”. In a case where the adhesion is 90% or more and 100% or less, the evaluation result is “Good” and is indicated by Symbol “Δ”. In a case where the adhesion is less than 90%, the evaluation result is “Poor” and is indicated by Symbol “x”. Use of the symbols for “Excellent”, “Good”, and “Poor” in the evaluation result is similar in the following.

The tape peeling evaluates a percentage of a remaining area of the electron transport layer 22 when an adhesive tape of polyimide film attached to the electron transport layer 22 is peeled off at an angle of 90 degrees. In a case where 100% of the area remains, the evaluation result is indicated by Symbol “o”. In a case where the area of 90% or more and less than 100% remains, the evaluation result is indicated by Symbol “Δ”. In a case where less than 90% of the area remains, the evaluation result is indicated by “x”.

The surface roughness of the electron transport layer 22 is finally the arithmetic mean roughness Ra of the surface of the particulate layer 222. It is to be noted that in the photoelectric conversion element 20B according to the second comparative example, because the particulate layer 222 is not formed, the arithmetic mean roughness Ra of the surface of the buffer layer 221 is evaluated.

FIG. 13A illustrates a state in which the particulate layer 222 is applied on the first electrode 21 in the photoelectric conversion element 20A according to the first comparative example. Coating spots occurred on the particulate layer 222, and the adhesion was not good. In addition, FIG. 13B illustrates a state in which the particulate layer 222 was peeled off from the first electrode 21 by the tape peeling in the photoelectric conversion element 20A. A part of the particulate layer 222 has been peeled off.

Therefore, in the photoelectric conversion element 20A according to the first comparative example, the evaluation results were obtained that the adhesion was “x” and the tape peeling was “x”. The arithmetic mean roughness Ra of the surface of the particulate layer 222 was 0.9.

In the photoelectric conversion element 20B according to the second comparative example, the evaluation results were obtained that the adhesion was “A” and the tape peeling was “Δ”. The arithmetic mean roughness Ra of the surface of the buffer layer 221 was 0.8.

The photoelectric conversion element 20B was further evaluated for electric properties. The electric properties are current-voltage properties, external quantum efficiency (EQE: External Quantum Efficiency) and responsiveness.

For the current-voltage properties, a voltage of −0.5 V to 1.0 V was applied between the first electrode 21 and the second electrode 24 to measure a current value. The measurement was carried out in a dark place and under light irradiation of a wavelength of 940 nm, and a dark current value (dashed line) and a bright current value (solid line) were measured.

The external quantum efficiency was calculated from the dark current value and the bright current value. In a case where the external quantum efficiency is 50% or more when a voltage of 0 V is applied between the first electrode 21 and the second electrode 24, the evaluation result is indicated by Symbol “o”. In a case where the external quantum effect is 30% or more and 50% or less, the evaluation result is indicated by Symbol “Δ”. In a case where the external quantum efficiency is less than 30%, the evaluation result is denoted by Symbol “x”.

For the responsiveness, a mean value until the bright current value reached 5% of ON time was calculated by applying a light pulse having a wavelength of 940 nm with the ON time of 10 ms and OFF time of 20 ms set and then turning off the irradiation. In a case where the responsiveness is 0.3 ms or less, the evaluation result was indicated by Symbol “o”. In a case where the responsiveness was 0.1 ms or less, the evaluation result was indicated by Symbol “Δ”. Then, in a case where the responsiveness was less than 1.0 ms, the evaluation result was indicated by Symbol “x”.

In the photoelectric conversion element 20B according to the second comparative example, the evaluation result was obtained that the external quantum efficiency was “x” and the responsiveness was “x”.

In contrast to the photoelectric conversion element 20A according to the first comparative example and the photoelectric conversion element 20B according to the second comparative example, the following evaluation results were obtained in the photoelectric conversion element 20(1) according to the first example to the photoelectric conversion element 20(3) according to the third example.

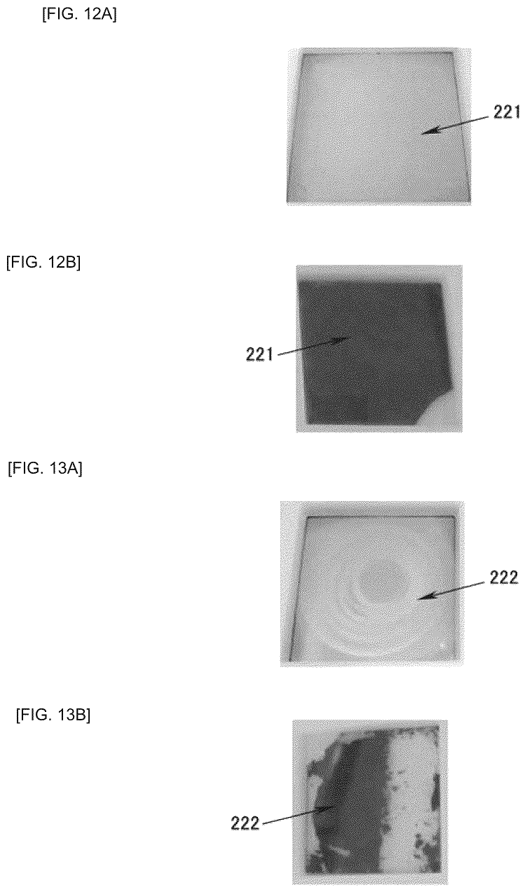

Here, FIG. 12A illustrates a state in which the electron transport layer 22 is applied on the first electrode 21 in the photoelectric conversion element 20(1) according to the first example. The electron transport layer 22 had no coating spots and good wettability. In addition, FIG. 12B illustrates a state in which the electron transport layer 22 was peeled off from the first electrode 21 by the tape peeling in the photoelectric conversion element 20(1). The electron transport layer 22 was scarcely peeled off.

Therefore, in the photoelectric conversion element 20(1) according to the first example, the evaluation results were obtained that the adhesion was “Δ” and the tape peeling was “Δ”. The arithmetic mean roughness Ra of the surface of the particulate layer 222 of the electron transport layer 22 was 0.9. Furthermore, in the photoelectric conversion element 20(1) according to the first example, the evaluation results were obtained that the external quantum effect was “Δ” and the responsiveness was “Δ”.

In the photoelectric conversion element 20(2) according to the second example, the evaluation results were obtained that the adhesion was “Δ” and the tape peeling was “x”. Because the high-temperature annealing was carried out in the film formation of the buffer layer 221 of the electron transport layer 22, crystallinity of the buffer 221 progressed and the surface roughness of the buffer layer 221 increased. This surface roughness of the buffer layer 221 was conveyed as the surface roughness of the particulate layer 222, and the arithmetic mean roughness Ra of the surface of the particulate layer 222 was 10.0. Furthermore, in the photoelectric conversion element 20(2) according to the second example, the evaluation results were obtained that the external quantum efficiency was “o” and the responsiveness was “Δ”.

In the photoelectric conversion element 20(3) according to the third example, the evaluation results were obtained that the adhesion was “A” and the tape peeling was “o”. Because the high-temperature annealing was carried out in the film formation of the buffer layer 221 of the electron transport layer 22, the crystallinity of the buffer layer 221 progressed and the surface roughness of the buffer layer 221 increased. This surface roughness of the buffer layer 221 was conveyed as the surface roughness of the particulate layer 222, and the arithmetic mean roughness Ra of the particulate layer 222 was 10.0. Furthermore, in the photoelectric conversion element 20(3) according to the third example, the organic functional groups were bonded to the surface of the particulates 222P and the surface defects of the particulates 222P were repaired. Therefore, the evaluation results were obtained that the external quantum efficiency was “o” and the responsiveness was “o”.

### (9) Schematic Configuration of the Electronic Apparatus 50

It is possible to apply the solid-state imaging device 1 according to the first embodiment as illustrated in FIG. 1 to various types of electronic apparatuses 50 such as an imaging system including a digital still camera or a digital video camera, a mobile phone with an imaging capability, or other equipment with the imaging capability, for example.

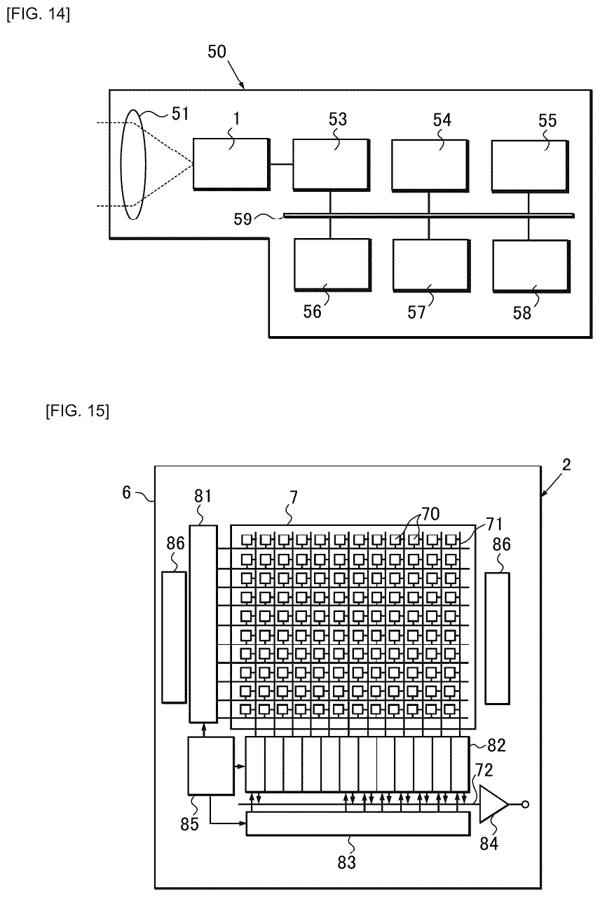

FIG. 14 is a block diagram illustrating a configuration of the electronic apparatus 50.

As illustrated in FIG. 14, the electronic apparatus 50 includes an optical system 51, the solid-state imaging device 1, a DSP (Digital Signal Processor) 53, a display device 54, an operation system 55, a memory 56, a recording device 57, and a power supply system 58. These are coupled to each other via a bus 59. The electronic apparatus 50 is able to capture static images and moving images.

The optical system 51 includes one or a plurality of lenses. The optical system 51 guides an image light (incident light) from a subject to the solid-state imaging device 1 and causes the light to form an image on a light receiving surface (sensor unit) of the solid-state imaging device 1.

In the solid-state imaging device 1, electrons are accumulated for a certain period of time according to the image formed on the light receiving surface through the optical system 51. Then, signals corresponding to the electrons accumulated on the solid-state imaging device 1 are supplied to the DSP 53.

The DSP 53 performs various types of signal processing on the signals from the solid-state imaging device 1 to acquire images. The DSP 53 causes the memory 56 to temporarily store data of the acquired images. The image data stored in the memory 56 is recorded in the recording device 57 or supplied to the display device 54 to display the images.

In addition, the operation system 55 receives various operations from users and supplies an operation signal to each of blocks of the electronic apparatus 50. The power supply system 58 supplies electric power necessary for driving each of the blocks of the electronic apparatus 50.

### Workings and Effects

As illustrated in FIG. 1 and FIG. 2, the solid-state imaging device 1 according to the first embodiment includes the photoelectric conversion element 20 including the first electrode 21, the electron transport layer 22, and the photoelectric conversion layer 23. Furthermore, the photoelectric conversion element 20 includes the second electrode 24. The first electrode 21 is disposed on the substrate 10. The photoelectric conversion layer 23 is disposed on the first electrode 21. The electron transport layer 22 is disposed between the first electrode 21 and the photoelectric conversion layer 23, and includes the buffer layer 221 and the particulate layer 222. The buffer layer 221 has the ionization potential larger than the work function of the first electrode 21 and the electron affinity larger than the photoelectric conversion layer 23. Then, the particulate layer 222 includes the particulates 222P that have the conductive zinc oxide as the main component. That is, the particulate layer 222 is disposed on the first electrode 21 via the buffer layer 221.

Therefore, it is possible to provide the photoelectric conversion element 20 that is able to improve the adhesion of the electron transport layer 22 to the first electrode 21 and to reduce peeling of the coated film without affecting the electric conductivity or the dispersibility of the particulates 222P.

In addition, as illustrated in FIG. 4, in the photoelectric conversion element 20, the particulate layer 222 of the electron transport layer 22 has the emission intensity ratio of the defect emission intensity L2 to the band-edge emission intensity L1 of the emission spectrum of 1 or more.

Therefore, it is possible to reduce the defects of the particulate layer 222 that is in contact with the photoelectric conversion layer 23 of the electron transport layer 22. This makes it possible to form an interface between the electron transport layer 22 with the reduced defects and the photoelectric conversion layer 23, thus allowing for improvement of the photoelectric conversion efficiency and the responsiveness of the photoelectric conversion element 20.

Furthermore, as illustrated in FIG. 3, in the photoelectric conversion element 20, the energy level of the conductor or the lowest unoccupied molecular orbital is deeper in the order of the photoelectric conversion layer 23, the particulate layer 222, and the buffer layer 221. Therefore, the electrons generated in the photoelectric conversion layer 23 are taken out to the first electrode 21 with no barrier block intervening, thus making it possible to improve the photoelectric conversion efficiency and the responsiveness of the photoelectric conversion element 20.

In addition, in the photoelectric conversion element 20, the mean primary particle size of the particulates 222P of the particulate layer 222 as illustrated in FIG. 2 is 1 nm or more and 20 nm or less. That is, because of a small diameter of the particulates 222P, the particulate layer 222 and the photoelectric conversion layer 23 are able to be in contact with each other without gaps. Therefore, the electrons generated in the photoelectric conversion layer 23 are taken out to the first electrode 21 with the electron transport layer 22 intervening, thus making it possible to improve the photoelectric conversion efficiency and the responsiveness of the photoelectric conversion element 20.

Furthermore, in the photoelectric conversion element 20, as illustrated in FIG. 2, the particulate layer 222 of the electron transport layer 22 is thicker than the buffer layer 221. Therefore, the particulate layer 222 with the reduced defects is thick, thus making it possible to improve the photoelectric conversion efficiency and the responsiveness of the photoelectric conversion element 20.

Moreover, the electron transport layer 22 is formed to be 400 nm or less, thus making it possible to efficiently take out the electrons generated in the photoelectric conversion layer 23 to the first electrode 21. Therefore, it is possible to improve the photoelectric conversion efficiency and the responsiveness of the photoelectric conversion element 20.

In addition, in the photoelectric conversion element 20, the organic functional groups are bonded to the surface of the particulates 222P of the particulate layer 222. Bonding the organic functional groups makes it possible to reduce the surface defects of the particulates 222P. Therefore, it is possible to increase the emission intensity ratio of the photoelectric conversion element 20. This makes it possible to improve the photoelectric conversion efficiency and the responsiveness of the photoelectric conversion element 20.

Furthermore, as illustrated in FIG. 5, in the method of manufacturing the solid-state imaging device 1, first, the first electrode 21 is formed on the substrate 10. Then, the buffer layer 221 having the n-semiconductor or the n-type organic semiconductor as the main component is formed by applying the ink liquid, in which the zinc precursor is dissolved, on the first electrode 21 and heating the ink liquid. The particulate layer 222 including the particulates 222P that include the conductive zinc oxide as the main component is formed on the buffer layer 221. This forms the electron transport layer 22 including the buffer layer 221 and the particulate layer 222.

Therefore, because the buffer layer 221 is formed by a coating process, it becomes possible to form the electron transport layer 22 including the buffer layer 221 and the particulate layer 222 by the coating process. This simplifies manufacturing processes of the solid-state imaging device 1. This also allows for reduction of manufacturing costs.

### 2. Second Embodiment

FIG. 15 is a schematic view of a configuration of an example of a CMOS imaging device 2 according to the second embodiment of the present disclosure. The solid-state imaging device 1 according to the first embodiment is configured as the CMOS imaging device 2 according to the second embodiment.

As illustrated in FIG. 15, the CMOS imaging device 2 includes a pixel region 7 and a peripheral circuit part on a semiconductor substrate 6. The semiconductor substrate 6 is a monocrystalline silicon substrate, for example. The pixel region 7 is an imaging region. In the image region 7, pixels 70 each including a plurality of photoelectric conversion elements are regularly arrayed two-dimensionally. The pixels 70 each include a photoelectric conversion element such as a photodiode and a plurality of pixel transistors. The plurality of pixel transistors includes three transistors of a transfer transistor, a reset transistor, and an amplification transistor, for example. In addition, the plurality of pixel transistors may include four transistors by further adding a selection transistor. These transistors are MOS transistors, for example.

Because an equivalent circuit of a unit pixel is similar as usual, detailed description is omitted. The pixel 70 may have a shared pixel structure. This pixel sharing structure includes a plurality of photodiodes, a plurality of transfer transistors, a shared floating diffusion, and another shared pixel transistor for one each.

The peripheral circuit part includes a vertical drive circuit 81, column signal processing circuits 82, a horizontal drive circuit 83, an output circuit 84, and a control circuit 85, or the like.

The control circuit 85 receives an input clock and data instructing an operating mode, or the like, and also outputs data such as internal information of the CMOS imaging device 2. That is, on the basis of a vertical synchronous signal, a horizontal synchronous signal, and a master clock, the control circuit 85 generates a clock signal or a control signal that serves as a criterion for operations of the vertical drive circuit 81, the column signal processing circuits 82, and the horizontal drive circuit 83, or the like. Then, these signals are inputted to the vertical drive circuit 81, the column signal processing circuits 82, and the horizontal drive circuit 83, or the like.

The vertical drive circuit 81 includes a shift register, for example. The vertical drive circuit 81 selects a pixel drive wiring line, supplies, to the selected pixel drive wiring line, pulses that drive the pixels 70, and drives the pixels 70 on a row-by-row basis. That is, the vertical drive circuit 81 sequentially selects and scans each of the pixels 70 in the pixel region 7 in a vertical direction on the row-by-row basis. The vertical drive circuit 81 supplies a pixel signal to the column signal processing circuits 82 through a vertical signal line 71, the pixel signal being based on signal charges generated according to an amount of light received by a photoelectric conversion element of each pixel 70.

The column signal processing circuits 82 is each disposed on each column of the pixels 70, for example. The column signal processing circuits 82 perform, for each pixel column, signal processing such as noise removal on signals outputted from one row of the pixels 70. That is, the column signal processing circuits 82 perform the signal processing such as CDS for removing fixed pattern noise unique to the pixels 70, signal amplification, or AD conversion. A horizontal selection switch, which is not illustrated, is coupled and provided between an output stage of the column signal processing circuits 82 and a horizontal signal line 72.

The horizontal drive circuit 83 includes the shift register, for example. By sequentially outputting horizontal scanning pulses, the horizontal drive circuit 83 selects each of the column signal processing circuits 82 in turn and causes each of the column signal processing circuits 82 to output a pixel signal to the horizontal signal line 72.

The output circuit 84 performs signal processing on the signal sequentially supplied from each of the column signal processing circuits 82 through the horizontal signal line 72 and outputs the signal. The output circuit 84 may perform only buffering, for example, or may perform black level adjustment, column variation correction, various digital signal processing, or the like. An input/output terminal 86 exchanges signals with outside.

### 3. Example of Practical Application to a Mobile Body

The technology (the present technology) according to the present disclosure is applicable to a variety of products. For example, the technology according to the present disclosure may be implemented as a device to be mounted on any type of mobile body such as an automobile, an electric vehicle, a hybrid electric vehicle, a motorcycle, a bicycle, a personal mobility, an airplane, a drone, a vessel, or a robot.

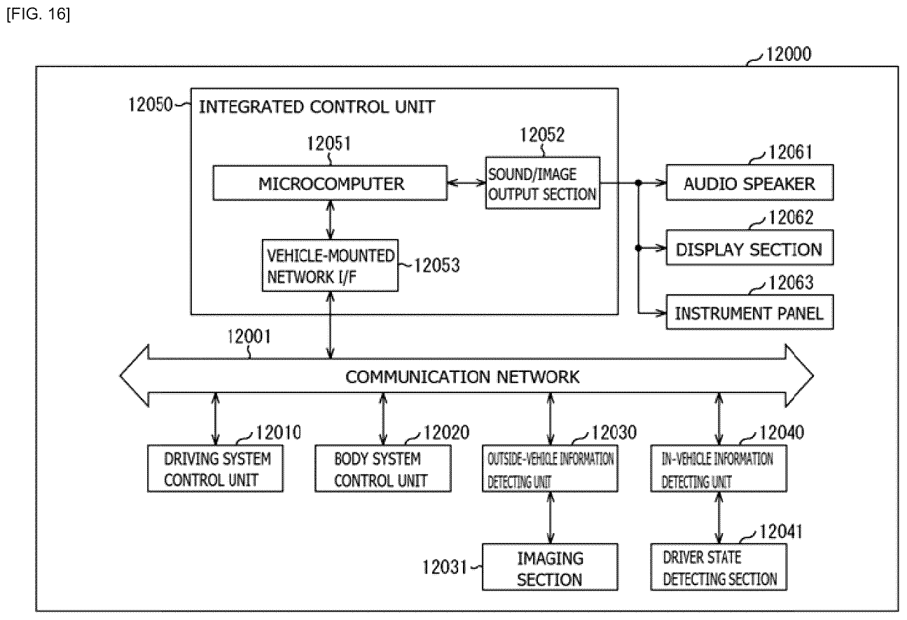

FIG. 16 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 16, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 16, an audio speaker 12061, a display section 12062, and an instrument panel 12063 are illustrated as the output device. The display section 12062 may, for example, include at least one of an on-board display and a head-up display.

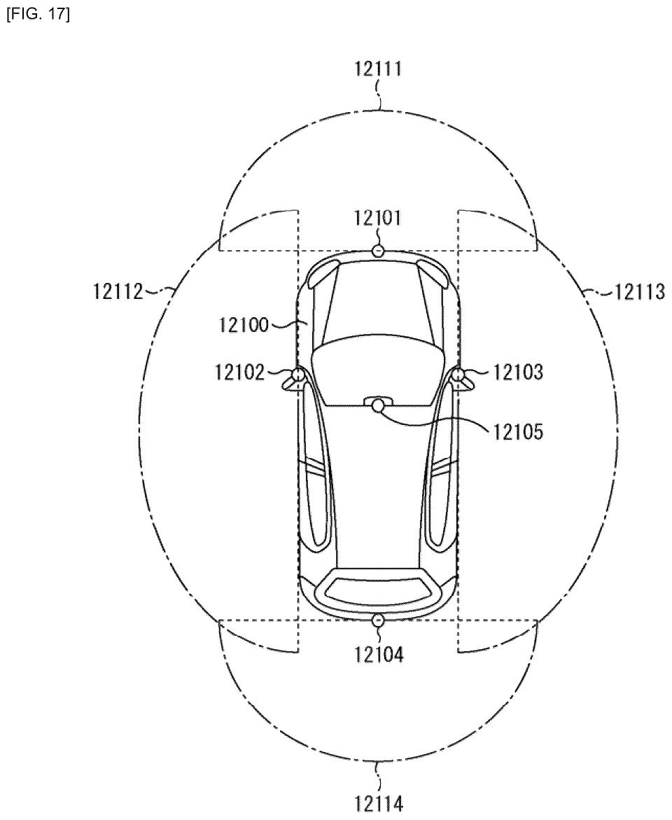

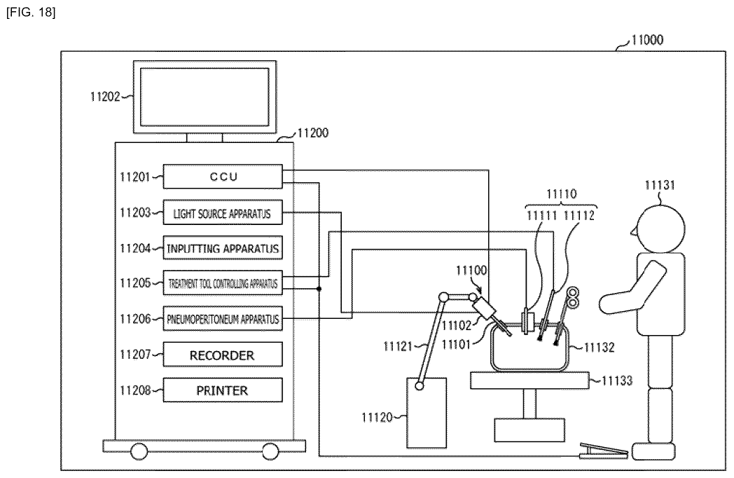

FIG. 17 is a diagram depicting an example of the installation position of the imaging section 12031.

In FIG. 17, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 17 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

As described above, description has been given of an example of the vehicle control system to which the technology according to the present disclosure may be applied. The technology according to the present disclosure may be applied to the imaging section 12031 among the configurations described above. By applying the technology according to the present disclosure to the imaging section 12031, it is possible to implement the imaging section 12031 with a simpler configuration.

### 4. Example of Practical Application to an Endoscopic Surgery System

The technology according to the present disclosure (the present technology) is applicable to a variety of products. For example, the technology according to the present disclosure may be applied to an endoscopic surgery system.

FIG. 18 is a view depicting an example of a schematic configuration of an endoscopic surgery system to which the technology according to an embodiment of the present disclosure (present technology) can be applied.

In FIG. 18, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

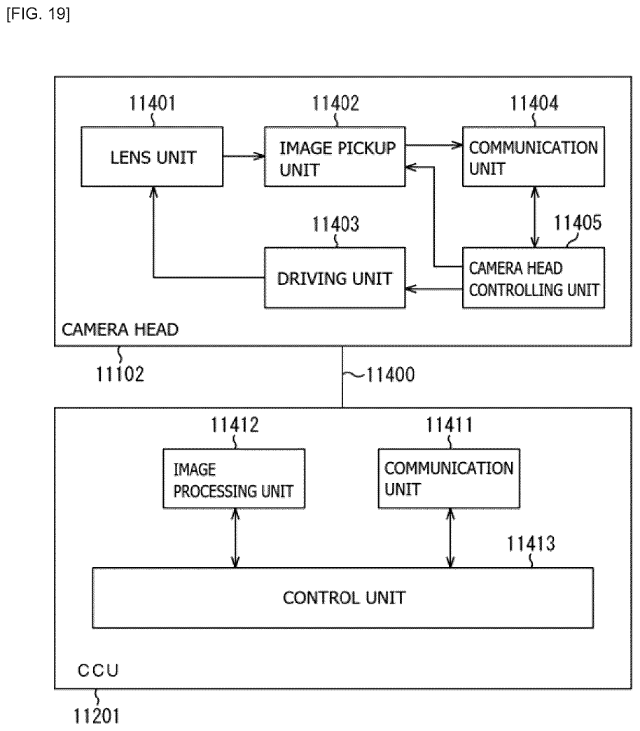

FIG. 19 is a block diagram depicting an example of a functional configuration of the camera head 11102 and the CCU 11201 depicted in FIG. 18.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

As described above, description has been given of an example of the endoscopic surgery system to which the technology according to the present disclosure may be applied. The technology according to the present disclosure may be applied to, for example, the image pickup unit 11402 of the camera head 11102 among the configurations described above. By applying the technology according to the present disclosure to the image pickup unit 11402, it is possible to obtain a good image of the surgical site, while achieving simplified structure.

It is to be noted that, although description has been given of the endoscopic surgery system, by way of example, the technology according to the present disclosure may be applied to any other, for example, microscopic surgery system, or the like.

### 5. Other Embodiments

The present technology is not limited to the foregoing embodiments and it is possible to modify the present technology in various ways without departing from the scope of the present technology.

In the present disclosure, a solid-state imaging device includes a photoelectric conversion element including a first electrode, an electron transport layer, and a photoelectric conversion layer. The first electrode is disposed on a substrate. The photoelectric conversion layer is disposed on the first electrode. The electron transport layer is disposed between the first electrode and the photoelectric conversion layer, and includes a buffer layer and a particulate layer. The buffer layer has an ionization potential larger than a work function of the first electrode and an electron affinity larger than the photoelectric conversion layer. Then, the particulate layer contains particulates containing conductive zinc oxide as a main component. That is, the particulate layer is disposed on the first electrode via the buffer layer.

Therefore, it is possible to provide a solid-state imaging device including the photoelectric conversion element that is able to improve the adhesion of the electron transport layer to the first electrode and to reduce peeling of the coated film without affecting the electric conductivity or the dispersibility of the particulates, and a method of manufacturing the solid-state imaging device.

### Configuration of the Present Technology

The present technology includes the following configuration. According to the present technology with the following configuration, it is possible to provide the solid-state imaging device including the photoelectric conversion element that is able to improve the adhesion of the electron transport layer to the first electrode and to reduce the peeling of the coated film without affecting the electric conductivity or the dispersibility of the particulates, and the method of manufacturing the solid-state imaging device.

(1)

A solid-state imaging device including a photoelectric conversion element,
the photoelectric conversion element including
a first electrode disposed on a substrate,
a photoelectric conversion layer disposed on the first electrode, and
an electron transport layer disposed between the first electrode and the photoelectric conversion layer and including a buffer layer and a particulate layer, the buffer layer having an ionization potential larger than a work function of the first electrode and an electron affinity larger than the photoelectric conversion layer, the particulate layer being disposed between the buffer layer and the photoelectric conversion layer and including particulates that contain conductive zinc oxide as a main component.
   (2)

The solid-state imaging device according to (1), in which the photoelectric conversion element further includes a second electrode disposed on the photoelectric conversion layer.

(3)

The solid-state imaging device according to (1) or (2), in which the conductive zinc oxide includes at least one selected from the group consisting of boron-doped zinc oxide, aluminum-doped zinc oxide, and gallium-doped zinc oxide.

(4)

The solid-state imaging device according to any one of (1) to (3), in which
the buffer layer includes a hole injection barrier against the first electrode, and
the buffer layer has higher mobility of electrons than mobility of holes.
   (5)

The solid-state imaging device according to (4), in which the buffer layer includes an n-semiconductor or an n-type organic semiconductor as the main component.

(6)

The solid-state imaging device according to (5), in which the n-type semiconductor includes at least one inorganic material selected from the group of TiO2, ZnO, ZnS, SrTiO3, Nb2O5, WO3, In2O3, CuTiO3, SnO2, InGaZnO4, InTiO2, and β-Ga203.

(7)

The solid-state imaging device according to (5), in which the n-type organic semiconductor includes an organic metal dye complex-formed with an organic material and a transition metal ion represented by phthalocyanine zinc (II); fullerene or a fullerene derivative; or a non-fullerene acceptor represented by an ITIC or BTP derivative.

(8)

The solid-state imaging device according to any one of (1) to (7), in which the particulate layer has an emission intensity ratio of defect emission intensity to band-edge emission intensity of an emission spectrum of 1 or more.

(9)

The solid-state imaging device according to any one of (1) to (8), in which an energy level of a conductor or a lowest unoccupied molecular orbital is deeper in the order of the photoelectric conversion layer, the particulate layer, and the buffer layer.

(10)

The solid-state imaging device according to any one of (1) to (9), in which a mean primary particle size of the particulates of the particulate layer is 1 nm or more and 20 nm or less.

(11)

The solid-state imaging device according to any one of (1) to (10), in which the particulate layer has a thickness larger than a thickness of the buffer layer.

(12)

The solid-state imaging device according to any one of (1) to (11), in which the electron transport layer has a thickness of 400 nm or less.

(13)

The solid-state imaging device according to any one of (1) to (12), in which organic functional groups are bonded to a surface of the particulates.

(14)

A method of manufacturing a solid-state imaging device, the method including:
forming a first electrode on a substrate;
forming a buffer layer that has an n-semiconductor or an n-type organic semiconductor as a main component by applying an ink liquid, in which a zinc precursor is dissolved, on the first electrode and heating the ink liquid; and
forming, on the buffer layer, a particulate layer including particulates that have conductive zinc oxide as a main component to form an electron transport layer of a photoelectric conversion element, the electron transport layer including the buffer layer and the particulate layer.

This application claims the benefits of Japanese Priority Patent Application JP2021-83843 filed with the Japan Patent Office on May 18, 2021, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. A solid-state imaging device comprising a photoelectric conversion element,
the photoelectric conversion element including
a first electrode disposed on a substrate,
a photoelectric conversion layer disposed on the first electrode, and
an electron transport layer disposed between the first electrode and the photoelectric conversion layer and including a buffer layer and a particulate layer, the buffer layer having an ionization potential larger than a work function of the first electrode and an electron affinity larger than the photoelectric conversion layer, the particulate layer being disposed between the buffer layer and the photoelectric conversion layer and including particulates that contain conductive zinc oxide as a main component.

2. The solid-state imaging device according to claim 1, wherein the photoelectric conversion element further includes a second electrode disposed on the photoelectric conversion layer.

3. The solid-state imaging device according to claim 1, wherein the conductive zinc oxide comprises at least one selected from the group consisting of boron-doped zinc oxide, aluminum-doped zinc oxide, and gallium-doped zinc oxide.

4. The solid-state imaging device according to claim 1, wherein
the buffer layer includes a hole injection barrier against the first electrode, and
the buffer layer has higher mobility of electrons than mobility of holes.

5. The solid-state imaging device according to claim 4, wherein the buffer layer includes an n-semiconductor or an n-type organic semiconductor as the main component.

6. The solid-state imaging device according to claim 5, wherein the n-type semiconductor comprises at least one inorganic material selected from the group of TiO2, ZnO, ZnS, SrTiO3, Nb2O5, WO3, In2O3, CuTiO3, SnO2, InGaZnO4, InTiO2, and β-Ga203.

7. The solid-state imaging device according to claim 5, wherein the n-type organic semiconductor comprises an organic metal dye complex-formed with an organic material and a transition metal ion represented by phthalocyanine zinc (II); fullerene or a fullerene derivative; or a non-fullerene acceptor represented by an ITIC or BTP derivative.

8. The solid-state imaging device according to claim 8, wherein the particulate layer has an emission intensity ratio of defect emission intensity to band-edge emission intensity of an emission spectrum of 1 or more.

9. The solid-state imaging device according to claim 1, wherein an energy level of a conductor or a lowest unoccupied molecular orbital is deeper in the order of the photoelectric conversion layer, the particulate layer, and the buffer layer.

10. The solid-state imaging device according to claim 1, wherein a mean primary particle size of the particulates of the particulate layer is 1 nm or more and 20 nm or less.

11. The solid-state imaging device according to claim 1, wherein the particulate layer has a thickness larger than a thickness of the buffer layer.

12. The solid-state imaging device according to claim 1, wherein the electron transport layer has a thickness of 400 nm or less.

13. The solid-state imaging device according to claim 1, wherein organic functional groups are bonded to a surface of the particulates.

14. A method of manufacturing a solid-state imaging device, the method comprising:
forming a first electrode on a substrate;
forming a buffer layer that has an n-semiconductor or an n-type organic semiconductor as a main component by applying an ink liquid, in which a zinc precursor is dissolved, on the first electrode and heating the ink liquid; and
forming, on the buffer layer, a particulate layer including particulates that have conductive zinc oxide as a main component to form an electron transport layer of a photoelectric conversion element, the electron transport layer including the buffer layer and the particulate layer.
